(19) United States
(12) Patent Application Publication
(10) Pub. No.: US 2025/0324565 A1
(43) Pub. Date: Oct. 16, 2025

(54) SEMICONDUCTOR DEVICE AND MANUFACTURING METHOD THEREOF

(71) Applicant: YANGTZE MEMORY TECHNOLOGIES CO., LTD., Wuhan (CN)

(72) Inventors: Zongliang Huo, Wuhan (CN); Zongke Xu, Wuhan (CN); Wei Xu, Wuhan (CN); Qiangwei Zhang, Wuhan (CN); Jinchang Sun, Wuhan (CN); Ran Xia, Wuhan (CN); Jiyue Song, Wuhan (CN)

(21) Appl. No.: 18/750,916

(22) Filed: Jun. 21, 2024

(30) Foreign Application Priority Data
Apr. 12, 2024 (CN) 202410445084.3

(51) Int. Cl. H10B 12/00

(52) U.S. Cl. CPC H10B 12/31; H10B 12/03; H10B 12/05; H10B 12/50

(57) ABSTRACT

According to one aspect of the present disclosure, a semiconductor device is provided. The semiconductor device may include a first semiconductor structure. The first semiconductor structure may include a stack structure comprising a first dielectric layer, a second dielectric layer, and a stack sub-structure stacked along a first direction. The first semiconductor structure may include a plurality of capacitor structures extending through the stack structure along the first direction. A size of a portion of the capacitor structure located in the first dielectric layer along a second direction may be greater than a size of a portion of the capacitor structure located in the second dielectric layer along the second direction. The second direction may be perpendicular to the first direction.

### CROSS-REFERENCE TO RELATED APPLICATIONS

The present application claims priority to Chinese Application No. 202410445084.3, filed on Apr. 12, 2024, which is hereby incorporated by reference in its entirety.

### TECHNICAL FIELD

The present disclosure relates to the field of semiconductor technology, e.g., to a semiconductor device and a manufacturing method thereof.

### BACKGROUND

With the continuous development of science and technology, semiconductor devices are widely applied in various electronic apparatuses and electronic products. For example, Dynamic Random Access Memory (DRAM), as a volatile memory, is a commonly used semiconductor memory device in computers.

### SUMMARY

According to one aspect of the present disclosure, a semiconductor device is provided. The semiconductor device may include a first semiconductor structure. The first semiconductor structure may include a stack structure comprising a first dielectric layer, a second dielectric layer, and a stack sub-structure stacked along a first direction. The first semiconductor structure may include a plurality of capacitor structures extending through the stack structure along the first direction. A size of a portion of the capacitor structure located in the first dielectric layer along a second direction may be greater than a size of a portion of the capacitor structure located in the second dielectric layer along the second direction. The second direction may be perpendicular to the first direction.

In some implementations, the first semiconductor structure may further include a plurality of vertical gate transistors. In some implementations, each of the vertical gate may be coupled to a corresponding one of the capacitor structures, and include a semiconductor pillar extending along the first direction and a gate structure in contact with at least part of a side of the semiconductor pillar.

In some implementations, a distance between one of two semiconductor pillars adjacent to a first semiconductor pillar of a plurality of semiconductor pillars along the second direction and the first semiconductor pillar may be a first distance, and a distance between the other one of the two semiconductor pillars and the first semiconductor pillar may be a second distance. In some implementations, the first distance may be greater than the second distance.

In some implementations, the plurality of semiconductor pillars may include a plurality of semiconductor pillar groups, and the semiconductor pillar group may include two semiconductor pillars arranged along the second direction. In some implementations, the gate structure may be located between the two semiconductor pillars of the semiconductor pillar group, and a distance between the two semiconductor pillars of the semiconductor pillar group may be the first distance. In some implementations, the first semiconductor structure further includes an isolation structure located between adjacent ones of the semiconductor pillar groups along the second direction, and a distance between two adjacent ones of the semiconductor pillar groups along the second direction may be the second distance.

In some implementations, the first semiconductor structure may further include a first insulation layer, and the isolation structure may include a second insulation layer. In some implementations, the first insulation layer may be located between the two semiconductor pillars of a semiconductor pillar group and may be in contact with the capacitor structure. In some implementations, the second insulation layer may be in contact with a capacitor structure. In some implementations, an etching-selectivity ratio of a material of the first dielectric layer to a material of the first insulation layer may be greater than 10:1. In some implementations, an etching-selectivity ratio of the material of the first dielectric layer to a material of the second insulation layer may be greater than 10:1.

In some implementations, an etching-selectivity ratio of a material of the first dielectric layer to a material of the second dielectric layer may be greater than 10:1.

In some implementations, a material of the second dielectric layer may be first silicon boronitride, and a formation temperature of the first silicon boronitride may range from 500° C. to 700° C. In some implementations, a material of the first dielectric layer may include at least one of second silicon boronitride, silicon nitride in a topological structure, or aluminum oxide. In some implementations, a formation temperature of the second silicon boronitride may range from 200° C. to 500° C.

In some implementations, the stack sub-structure may include a first conductive layer, a first support layer, a second conductive layer, and a second support layer stacked along the first direction. In some implementations, a capacitor structure of the plurality of capacitor structure may include a first electrode plate, a dielectric layer, a second electrode plate, and a support structure. In some implementations, the first electrode plate may extend into the second dielectric layer and the first dielectric layer from the stack sub-structure along the first direction. In some implementations, the support structure may be located in the stack sub-structure and extends along the first direction, and the first electrode plate may surround the support structure. In some implementations, a portion of the second electrode plate may surround the first conductive layer and the second conductive layer. In some implementations, the dielectric layer may be located between the first electrode plate and the second electrode plate. In some implementations, a size of a portion of the support structure and the first electrode plate located in the stack sub-structure along the second direction may be greater than the size of the portion of the capacitor structure located in the second dielectric layer along the second direction.

In some implementations, a material of the first dielectric layer may be different from a material of the first support layer, and may be different from a material of the second support layer.

In some implementations, an etching-selectivity ratio of a material of the first dielectric layer to a material of the first support layer may be greater than 10:1, and an etching-selectivity ratio of the material of the first dielectric layer to a material of the second support layer may be greater than 10:1.

In some implementations, the size of the portion of the capacitor structure located in the first dielectric layer along the second direction may range from 16 nm to 55 nm, the size of the portion of the capacitor structure located in the second dielectric layer along the second direction may range from 10 nm to 40 nm, and the size of the portion of the support structure and the first electrode plate located in the stack sub-structure along the second direction may range from 10 nm to 40 nm.

In some implementations, a side of the portion of a capacitor structure located in the first dielectric layer that is in contact with the second dielectric layer may be a plane.

In some implementations, the first semiconductor structure may further include a plurality of contact structures extending along the first direction. In some implementations, one of two opposite ends of the semiconductor pillar along the first direction may be in contact with the contact structure.

In some implementations, a contact structure may include a first end face and a second end face that are opposite along the first direction. In some implementations, the capacitor structure may include a third end face and a fourth end face that are opposite along the first direction. In some implementations, at least part of the first end face may be in contact with the third end face.

In some implementations, a ratio of an area of a portion of the first end face in contact with the third end face to an area of the first end face may range from 25% to 100%.

In some implementations, the first end face of at least some of the contact structures may be in contact with both the third end face and the first dielectric layer.

In some implementations, a size of a contact structure along the second direction may range from 4 nm to 20 nm.

In some implementations, the semiconductor device may further include a second semiconductor structure. In some implementations, the first semiconductor structure and the second semiconductor structure may be stacked along the first direction, and the second semiconductor structure may include a peripheral circuit.

According to another aspect of the present disclosure, a method of manufacturing a semiconductor device is provided. The method may include forming a first semiconductor structure. The forming the first semiconductor structure may include forming a stack structure comprising a first dielectric layer, a second dielectric layer, and a stack sub-structure stacked along a first direction. The forming the first semiconductor structure may include forming a plurality of capacitor structures extending through the stack structure along the first direction. A size of a portion of the capacitor structure located in the first dielectric layer along a second direction may be greater than a size of a portion of the capacitor structure located in the second dielectric layer along the second direction. The second direction may be perpendicular to the first direction.

In some implementations, the forming the first semiconductor structure may further include forming a plurality of vertical gate transistors. In some implementations, each of the vertical gate transistors may be coupled to a corresponding one of the capacitor structures, and may include a semiconductor pillar extending along the first direction and a gate structure in contact with at least part of a side of the semiconductor pillar.

In some implementations, a distance between one of two semiconductor pillars adjacent to a first semiconductor pillar of a plurality of semiconductor pillars along the second direction and the first semiconductor pillar may be a first distance, and a distance between the other one of the two semiconductor pillars and the first semiconductor pillar may be a second distance. In some implementations, the first distance may be greater than the second distance.

In some implementations, a material of the second dielectric layer may include first silicon boronitride, and a formation temperature of the first silicon boronitride may range from 500° C. to 700° C. In some implementations, a material of the first dielectric layer comprises at least one of second silicon boronitride, silicon nitride in a topological structure, or aluminum oxide. In some implementations, a formation temperature of the second silicon boronitride may range from 200° C. to 500° C.

In some implementations, the forming the stack structure and forming the plurality of capacitor structures may include providing an initial stack structure including the first dielectric layer, the second dielectric layer, and an initial stack sub-structure stacked along the first direction. In some implementations, the forming the stack structure and forming the plurality of capacitor structures may include etching the initial stack structure to form a plurality of through holes extending through the initial stack structure along the first direction. In some implementations, the forming the stack structure and forming the plurality of capacitor structures may include performing first wet etching on the first dielectric layer such that a size of a portion of a through hole located in the first dielectric layer along the second direction is greater than a size of a portion of the through hole located in the second dielectric layer along the second direction.

In some implementations, an etching-selectivity ratio of a material of the first dielectric layer to a material of the second dielectric layer may be greater than 10:1, and an etching-selectivity ratio of the material of the first dielectric layer to a material of the initial stack sub-structure may be greater than 10:1.

In some implementations, the initial stack sub-structure may include a first sacrificial layer, a first support layer, a second sacrificial layer, and a second support layer stacked along the first direction. In some implementations, the forming the plurality of capacitor structures may further include performing second wet etching on the through hole such that a size of a portion of the through hole located in the first sacrificial layer along the second direction is enlarged.

In some implementations, the forming the plurality of capacitor structures may further include forming a first electrode plate on a sidewall and a bottom wall of the through hole. In some implementations, the forming the plurality of capacitor structures may further include forming a support structure covering the first electrode plate in the through hole where the first electrode plate is formed.

In some implementations, the forming the plurality of capacitor structures may further include removing the first sacrificial layer to form a first filling region, and removing the second sacrificial layer to form a second filling region. In some implementations, the forming the plurality of capacitor structures may further include forming a dielectric layer and a second electrode plate on the first filling region, the second filling region, and the second support layer, wherein the dielectric layer is located between the first electrode plate and the second electrode plate. In some implementations, the forming the plurality of capacitor structures may further include forming a first conductive layer in the first filling region, and forming a second conductive layer in the second filling region. In some implementations, the second electrode plate may surround the first conductive layer and the second conductive layer.

In some implementations, the forming the first semiconductor structure may further include forming a plurality of contact structures extending along the first direction. In some implementations, one of two opposite ends of the semiconductor pillar along the first direction may be in contact with the contact structure.

In some implementations, the method may further include forming a second semiconductor structure including a peripheral circuit. In some implementations, the method may further include bonding the first semiconductor structure and the second semiconductor structure such that the first semiconductor structure and the second semiconductor structure are stacked along the first direction.

According to a further aspect of the present disclosure, a memory device is provided. The memory device may include a semiconductor device. The semiconductor device may include a first semiconductor structure. The first semiconductor structure may include a stack structure comprising a first dielectric layer, a second dielectric layer, and a stack sub-structure stacked along a first direction. The first semiconductor structure may include a plurality of capacitor structures extending through the stack structure along the first direction. A size of a portion of the capacitor structure located in the first dielectric layer along a second direction may be greater than a size of a portion of the capacitor structure located in the second dielectric layer along the second direction. The second direction may be perpendicular to the first direction. The memory device may include a peripheral circuit coupled to the semiconductor device and configured to control at least one operation of the semiconductor device.

### BRIEF DESCRIPTION OF THE DRAWINGS

FIG. 1 is a schematic view of an electronic apparatus provided by examples of the present disclosure.

FIG. 2 is a schematic view of a memory provided by examples of the present disclosure.

FIG. 3 is a schematic cross-sectional view I of a semiconductor device provided by examples of the present disclosure.

FIG. 4 is a schematic top view I of a semiconductor device provided by examples of the present disclosure.

FIG. 5 is a schematic top view II of a semiconductor device provided by examples of the present disclosure.

FIG. 6 is a schematic top view III of a semiconductor device provided by examples of the present disclosure.

FIG. 7 is a schematic cross-sectional view II of a semiconductor device provided by examples of the present disclosure.

FIG. 8 is a schematic top view IV of a semiconductor device provided by examples of the present disclosure.

FIG. 9 is a schematic top view V of a semiconductor device provided by examples of the present disclosure.

FIG. 10 is a flow diagram of a method of forming a semiconductor device provided by examples of the present disclosure.

FIGS. 11 to 18 are schematic views of a formation process of a semiconductor device provided by examples of the present disclosure.

### DETAILED DESCRIPTION

Example implementations disclosed by the present disclosure will be described below in more details with reference to the drawings. Although the example implementations of the present disclosure are shown in the drawings, it is to be understood that the present disclosure may be implemented in various forms and should not be limited by the specific implementations set forth herein. Rather, these implementations are provided for a more thorough understanding of the present disclosure, and to fully convey a scope disclosed by the present disclosure to those skilled in the art.

In the following description, numerous specific details are given in order to provide a more thorough understanding of the present disclosure. However, it is apparent to those skilled in the art that the present disclosure may be practiced without one or more of these details. In other examples, in order to avoid confusion with the present disclosure, some technical features well-known in the field are not described. That is, not all the features of the actual examples are described herein, and well-known functions and structures are not described in detail.

In the drawings, like reference numerals denote like elements throughout the specification.

It is to be understood that, spatially relative terms, such as “beneath”, “below”, “lower”, “under”, “over”, “upper”, and the like, may be used herein for ease of description to describe the relationship between one element or feature and other elements or features as illustrated in the figures. It is to be understood that the spatially relative terms are intended to further encompass different orientations of a device in use or operation in addition to the orientation depicted in the figures. For example, if the device in the drawings is turned over, then the elements or the features described as “below” or “under” or “beneath” other elements may be oriented “on” the other elements or features. Thus, the example terms, “below” and “beneath”, may comprise both upper and lower orientations. The device may be orientated otherwise (rotated by 90 degrees or in other orientations), and the spatially descriptive terms used herein are interpreted accordingly.

The terms used herein are only intended to describe the particular examples, and are not used as limitations of the present disclosure. As used herein, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” comprises any and all combinations of related items listed.

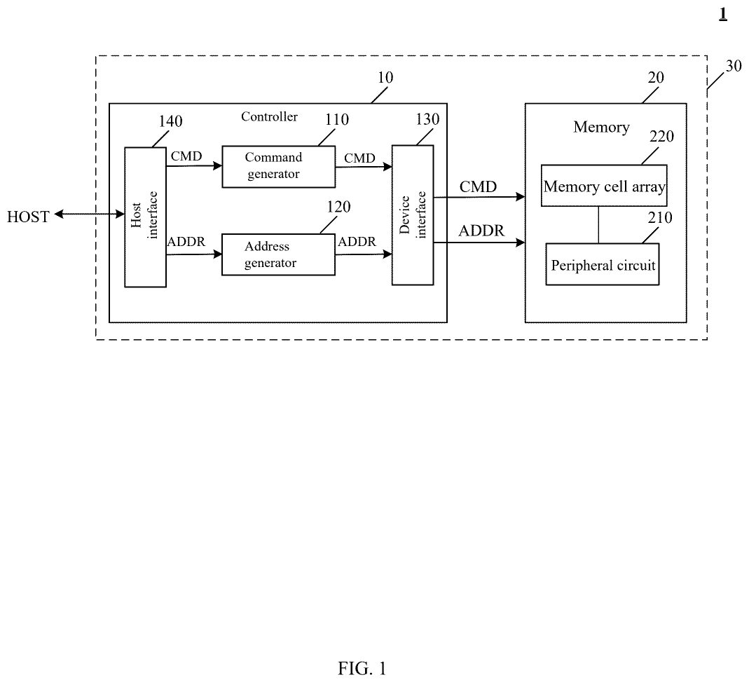

FIG. 1 is a schematic diagram illustrating an electronic apparatus 1, according to examples of the present disclosure. The electronic apparatus 1 may include a mobile phone, a desktop computer, a laptop computer, a tablet computer, a vehicle computer, a gaming console, a printer, a positioning apparatus, a wearable electronic apparatus, a smart sensor, a virtual reality (VR) apparatus, an augmented reality (AR) apparatus, or any other suitable electronic apparatus having a memory therein.

As shown in FIG. 1, the electronic apparatus 1 may include a HOST and a memory system 30. The memory system 30 has one or more memories 20 and a controller 10. The HOST may be a processor of an electronic apparatus (e.g., a central processing unit (CPU)), or a system on chip (SoC) (e.g., an application processor (AP)). The HOST may be configured to send or receive data to or from the memory 20. The controller 10 is coupled to the memory 20 and the HOST, and is configured to control the memory 20. The controller 10 can manage the data stored in the memory 20 and communicate with the HOST.

The controller 10 may be configured to control operations of the memory 20, such as read, erase, write, and refresh operations. In some implementations, the controller 10 is further configured to process an error correction code (ECC) with respect to the data read from or written to the memory 20. The controller 10 may further perform any other suitable functions, e.g., formatting the memory 20.

In some examples, the controller 10 and the one or more memories 20 may be integrated into various types of storage apparatuses. For example, the controller 10 may be integrated into a north bridge of a computer mainboard or directly integrated into a computer CPU, and a plurality of memories 20 may be integrated into a memory module. That is to say, the memory system 30 may be implemented and packaged into different types of end electronic products.

The controller 10 may send or receive data to or from the HOST, and may send a command CMD and an address ADDR to the memory 20. The controller 10 may include a command generator 110, an address generator 120, an device interface 130 and a host interface 140. The host interface 140 may receive a command CMD and an address ADDR from the HOST. The command generator 110 may generate an access command, a refresh command, and the like by decoding the command CMD received from the HOST, and may provide the access command and the refresh command to the memory 20 through the device interface 130. The access command may be a signal that instructs the memory 20 to write or read data by accessing a row of a memory cell array 220 corresponding to the address ADDR. The refresh command may be a signal that instructs the memory 20 to read or rewrite data by accessing and refreshing a row of the memory cell array 220 corresponding to the address ADDR.

The address generator 120 in the controller 10 may generate a row address and a column address to be accessed in the memory cell array 220 by decoding the address ADDR received from the host interface 140. Moreover, the memory 20 may generate an address of a memory bank to be accessed when the memory cell array 220 includes a plurality of memory banks.

The controller 10 may control memory operations such as write and read by providing various signals to the memory 20 via the device interface 130. For example, the controller 10 may provide a write command to the memory 20. The write command is used to instruct the memory 20 to perform the write operation to store data into the memory 20.

In some examples, the memory 20 includes at least one chip. Each chip includes at least one memory bank. Each memory bank includes at least one memory block. Each memory block includes a memory cell array 220 and a peripheral circuit 210. The memory cell array includes a plurality of memory cell rows and a plurality of memory cell columns. Each memory cell row is coupled with one corresponding word line, and each memory cell column is coupled with one corresponding bit line. The peripheral circuit 210 may write or read data to or from the memory cell array 220 based on the command CMD and the address ADDR received from the controller 10, or may provide a control signal CTRL for refreshing a memory cell included in the memory cell array 220 to a row decoder and a column decoder. In other words, the peripheral circuit 210 may perform all operations to process the data in the memory cell array 220. The peripheral circuit 210 may include: a control circuit corresponding to each memory block, such as a sensing amplifier (SA) circuit, a word-line driver (WLD) circuit, etc.; a control circuit corresponding to each memory bank, such as a row decoder, a column decoder, etc.; and a control circuit corresponding to all the memory banks, such as a command buffer, a command decoder, an address buffer, a data input/output buffer, a mode register, etc.

The memory 20 may be a random access memory (RAM), such as a dynamic random access memory (DRAM), a synchronous DRAM (SDRAM), a static RAM (SRAM), a double data rate SDRAM (DDR SDRAM), a DDR2 SDRAM, a DDR3 SDRAM, a phase change RAM (PRAM), a magnetic RAM (MRAM), a resistive RAM (RRAM), etc. The following description is made by taking the DRAM memory as an example.

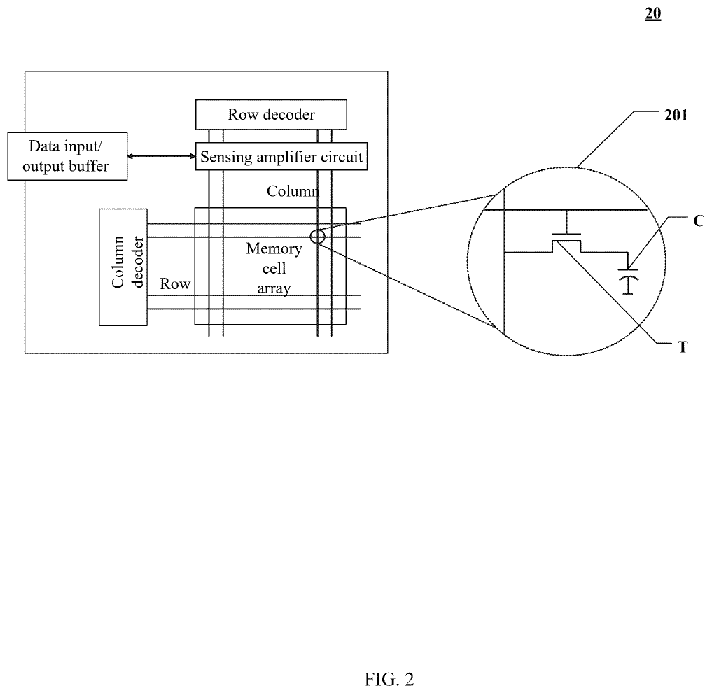

FIG. 2 is a schematic diagram illustrating a dynamic random access memory, according to examples of the present disclosure. With reference to FIG. 2, the dynamic random access memory includes a memory cell array and a peripheral circuit. The memory cell array includes a plurality of memory cells 201 arranged in an array. Each memory cell 201 includes one transistor (T) and one capacitor (C). A word line is coupled to a gate of the transistor T, and a bit line is coupled to a drain of the transistor T. The main operation principle of the memory cell is to utilize the amount of charges stored in the capacitor to represent whether a binary bit is 1 or 0. The memory cells are arranged in an array, and the memory cell array uses a row and a column to designate an address. By designating an intersection of a row and a column (by designating a row address and a column address of the DRAM), the controller may independently access various memory cells in a DRAM chip, and perform the read, write or refresh operation on the data stored therein.

With the development of dynamic random access memory technology, the size of the memory cell is increasingly smaller, and its array architecture has changed from 8F2 to 6F2 and to 4F2. An architecture of the transistor in the memory cell has been gradually developed to a vertical gate transistor from a planar array transistor, thereby forming an architecture of a three-dimensional memory.

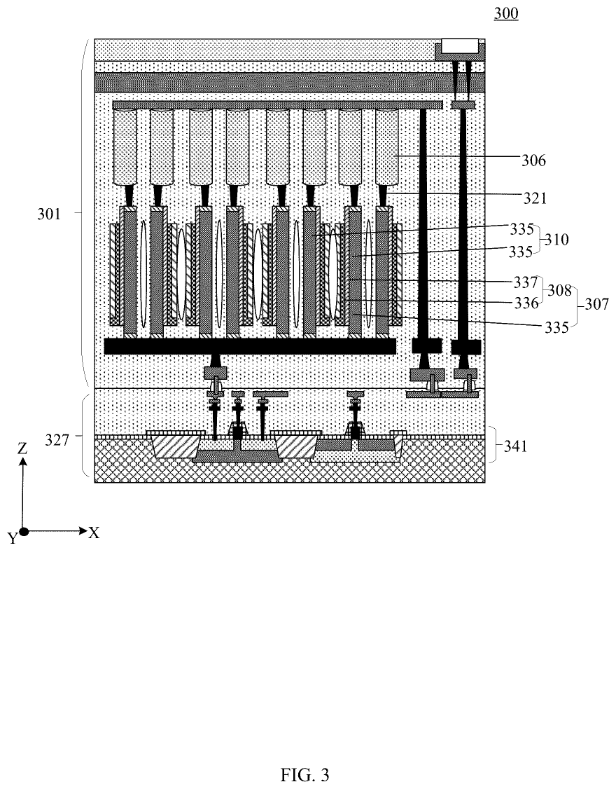

As shown in FIG. 3, examples of the present disclosure provide a semiconductor device 300 including a first semiconductor structure 301. The first semiconductor structure 301 includes a plurality of vertical gate transistors 307, where each of the vertical gate transistors 307 is coupled to a corresponding one of the capacitor structures 306. The vertical gate transistor 307 includes a semiconductor pillar 335 extending along the first direction and a gate structure 308 in contact with at least part of a side of the semiconductor pillar 335.

In an architecture of the vertical gate transistor, the semiconductor pillar 335 of the vertical gate transistor 307 extends along the first direction. One of two opposite ends of the semiconductor pillar 335 along the first direction needs to be coupled with the capacitor structure 306 through the contact structure 321. The size of the semiconductor pillar 335 of the vertical gate transistor 307 along a direction perpendicular to the first direction is small such that an overlap window from the contact structure 321 to the capacitor structure 306 is narrow, which affects the performance of the memory. Moreover, with the continuous miniaturization of the memory, both the size of the semiconductor pillar 335 of the vertical gate transistor 307 along the direction perpendicular to the first direction and the size of the capacitor structure 306 along the direction perpendicular to the first direction will be increasingly smaller, such that the overlap window from the contact structure 321 to the capacitor structure 306 will become increasingly narrower. Therefore, it may be beneficial to enlarge the overlap window from the contact structure 321 to the capacitor structure 306.

In some examples, the gate structure 308 in contact with at least part of the side of the semiconductor pillar 335 may be construed such that the gate structure 308 may be located on one side, two sides, three sides or four sides of the semiconductor pillar 335.

In some examples, a material of the semiconductor pillars 335 includes, but is not limited to, an elemental semiconductor material (e.g., silicon (Si) or germanium (Ge), etc.), a group III-V compound semiconductor material (e.g., gallium nitride (GaN), gallium arsenide (GaAs), or indium phosphide (InP), etc.), a group II-VI compound semiconductor material (e.g., zinc sulfide (ZnS), cadmium sulfide (CdS) or cadmium telluride (CdTe), etc.), an organic semiconductor material, or other semiconductor materials known in the art.

In the examples of the present disclosure, the gate structure 308 includes a gate 336 and a gate insulation layer 337. Here, a material of the gate 336 includes a conductive material, e.g., at least one of tungsten, tantalum, titanium, nickel, platinum, titanium nitride, tungsten nitride and tantalum nitride. A material of the gate insulation layer 337 includes, but is not limited to, silicon oxide, silicon nitride or silicon oxynitride, etc. A formation process of the gate insulation layer 337 and the gate 336 includes a thin film deposition process.

The first direction in the examples of the present disclosure may be construed as a Z axis direction in the drawings, the second direction may be construed as an X axis direction in the drawings, and the third direction may be construed as a Y axis direction in the drawings.

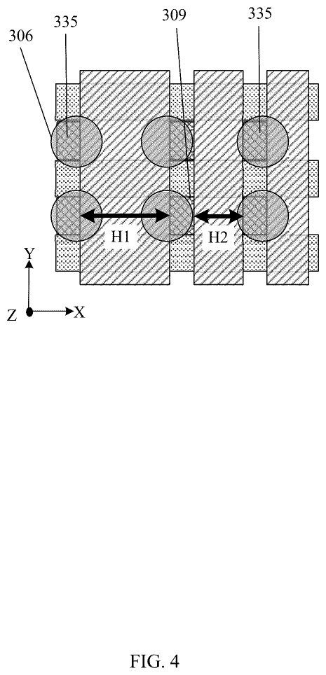

In some examples, as shown in FIG. 4, a distance between one of two semiconductor pillars 335 adjacent to a first semiconductor pillar 309 of a plurality of semiconductor pillars 335 along the second direction and the first semiconductor pillar 309 is a first distance H1, and a distance between the other one of the two semiconductor pillars 335 and the first semiconductor pillar 309 is a second distance H2; and the first distance is greater than the second distance.

In some examples, as shown in FIG. 4, the plurality of semiconductor pillars 335 are arranged in an array along the second direction and a third direction. Here, the third direction and the second direction intersect and both are perpendicular to the first direction. An example illustration is made in the present disclosure by taking the second direction as being perpendicular to the third direction as an example.

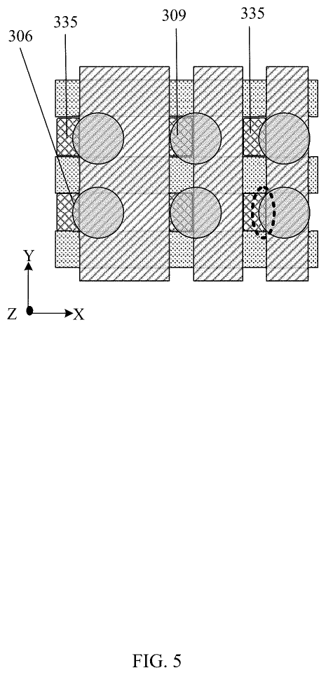

The first semiconductor pillar 309 may be any one of the plurality of semiconductor pillars 335. The distance between one of two semiconductor pillars 335 adjacent to the first semiconductor pillar 309 along the second direction and the first semiconductor pillar 309 is greater than the distance between the other one of the two semiconductor pillars 335 and the first semiconductor pillar 309. The plurality of semiconductor pillars 335 arranged along the second direction are non-uniformly distributed. However, in order to obtain the maximum density of the capacitor structures, the capacitor structures are designed to be arranged as uniformly as possible, thus resulting in an offset between the center of the capacitor structure 306 and the center of the semiconductor pillar 335 in a design structure as shown in FIGS. 3 and 4, e.g., an offset between the center of the contact structure and the center of the capacitor structure. Due to a small area of an end face of the semiconductor pillar 335 in contact with the contact structure 321, and in consideration of certain differences between the sizes of the capacitor structure 306 and the contact structure 321 themselves and design sizes during process procedures and the limited achievable capability of the overlay accuracy of lithography on production lines, it may easily cause a contact area of some of the contact structures 321 with the capacitor structure 306 as shown at a broken line box in FIG. 5 to be below the minimum requirement. Consequently, it fails to meet the electrical requirements, and affects the performance of the semiconductor device.

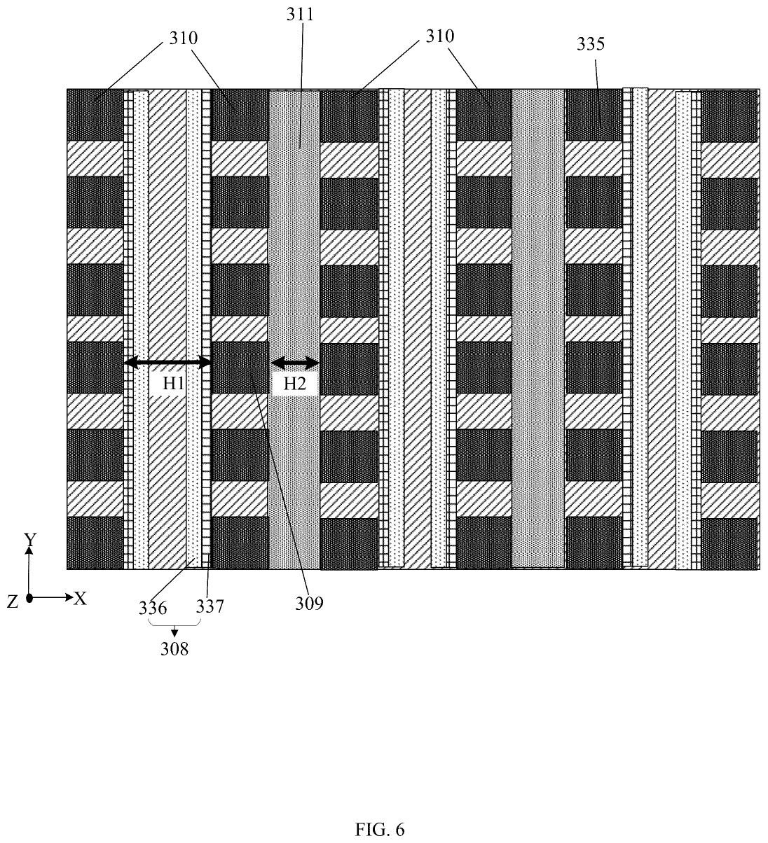

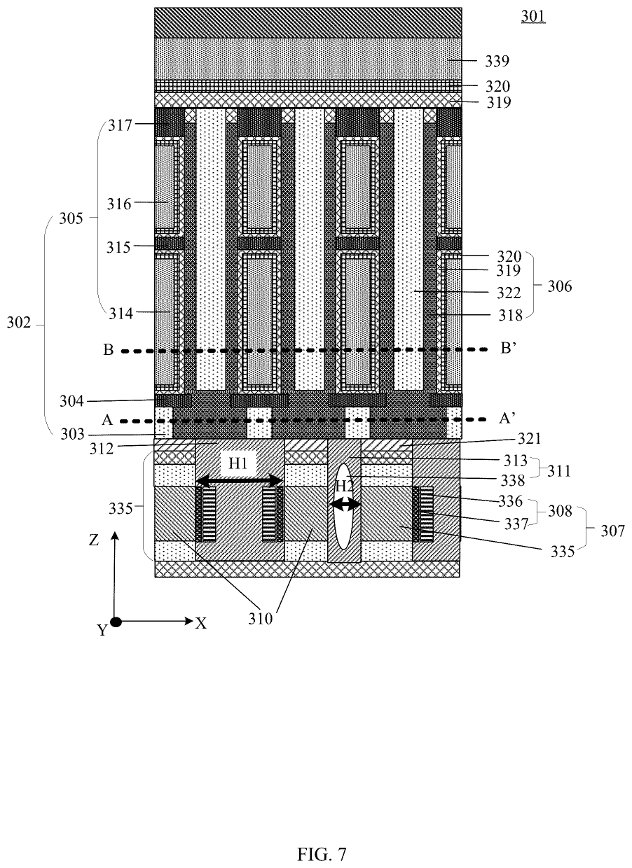

In some examples, as shown in FIGS. 6 and 7, the plurality of semiconductor pillars 335 constitute a plurality of semiconductor pillar groups 310, and the semiconductor pillar group 310 includes two semiconductor pillars 335 arranged along the second direction; the gate structure 308 is located between the two semiconductor pillars 335 of the semiconductor pillar group 310, and a distance between the two semiconductor pillars 335 of the semiconductor pillar group 310 is the first distance H1; the first semiconductor structure 301 further includes an isolation structure 311 located between adjacent ones of the semiconductor pillar groups 310 along the second direction, and a distance between two adjacent ones of the semiconductor pillar groups 310 along the second direction is the second distance H2.

In some examples, as shown in FIGS. 6 and 7, the plurality of semiconductor pillars 335 constitute a plurality of rows of semiconductor pillars arranged along the third direction and a plurality of columns of semiconductor pillars arranged along the second direction. The row of semiconductor pillars includes a plurality of semiconductor pillars 335 arranged along the second direction, and the column of semiconductor pillars includes a plurality of semiconductor pillars 335 arranged along the third direction. The gates 336 of the gate structures 308 that are respectively in contact with the plurality of semiconductor pillars in the same column of semiconductor pillars are connected with one another to constitute a word line extending along the third direction. The plurality of semiconductor pillar groups 310 are arranged in an array along the second direction and the third direction, and the semiconductor pillar group 310 includes two semiconductor pillars 335 extending along the second direction. The gate structures 308 that are respectively in contact with the two semiconductor pillars 335 in the semiconductor pillar group 310 are both located between the two semiconductor pillars 335 in the semiconductor pillar group 310. The isolation structure 311 is located between adjacent ones of the semiconductor pillar groups 310 along the second direction. Here, the isolation structure 311 may be a second insulation layer, or the second insulation layer in which an air gap is formed, or the second insulation layer in which a conductive structure is formed.

It may be understood that two gate structures 308 need to be formed between the two semiconductor pillars 335 in the semiconductor pillar group 310, the gate structure 308 includes the gate 336 and the gate insulation layer 337 between the gate 336 and the semiconductor pillar 335, and an insulation layer further needs to be formed between the two gate structures 308 to isolate the two gate structures 308, whereas only the isolation structure 311 needs to be formed between the adjacent ones of the semiconductor pillar groups 310 along the second direction. That is to say, the structure formed between the two semiconductor pillars 335 of the semiconductor pillar group 310 is more complex than the structure formed between the adjacent ones of the semiconductor pillar groups 310 along the second direction, such that the distance between the two semiconductor pillars 335 of the semiconductor pillar group 310 is greater than the distance between the adjacent ones of the semiconductor pillar groups 310 along the second direction. Accordingly, the plurality of semiconductor pillars 335 arranged along the second direction are non-uniformly distributed. However, in order to obtain the maximum density of the capacitor structures 306, the capacitor structures 306 are designed to be arranged as uniformly as possible, thus resulting in the problem that the contact area between the contact structure 321 and the capacitor structure 306 as described in the aforementioned examples is prone to be below the minimum requirement. Consequently, it fails to meet the electrical requirements, and affects the performance of the semiconductor device.

In some examples, as shown in FIG. 7, the semiconductor device 300 includes a first semiconductor structure 301, where the first semiconductor structure 301 includes: a stack structure 302 including a first dielectric layer 303, a second dielectric layer 304, and a stack sub-structure 305 stacked along a first direction; and a plurality of capacitor structures 306 extending through the stack structure 302 along the first direction, where a size of a portion of the capacitor structure 306 located in the first dielectric layer 303 along a second direction is greater than a size of a portion of the capacitor structure 306 located in the second dielectric layer 304 along the second direction; and the second direction is perpendicular to the first direction.

In the examples of the present disclosure, the first semiconductor structure 301 includes the stack structure 302 including the first dielectric layer 303, the second dielectric layer 304, and the stack sub-structure 305 stacked along the first direction. The size of the portion of the capacitor structure 306 located in the first dielectric layer 303 along the second direction is greater than the size of the portion of the capacitor structure 306 located in the second dielectric layer 304 along the second direction. In the examples of the present disclosure, adding the first dielectric layer 303 may lead to an increased size of the bottom of the capacitor structure 306 along the second direction, an increased contact area between the contact structure 321 and the capacitor structure 306, and an enlarged process window, such that the contact structure 321 can still be in good contact with the bottom of the capacitor structure 306 in a case where the size of the contact structure 321 in contact with the bottom of the capacitor structure 306 is small and there is an offset between the center of the contact structure 321 and the center of the capacitor structure 306 in design. Thus, the performance of the semiconductor device 300 can be improved.

In some examples, as shown in FIG. 7, the first dielectric layer 303, the second dielectric layer 304 and the stack sub-structure 305 in the stack structure 302 are stacked from bottom to top.

In some examples, as shown in FIG. 7, the first semiconductor structure 301 further includes a first insulation layer 312, and the isolation structure 311 includes a second insulation layer 313; the first insulation layer 312 is located between the two semiconductor pillars 335 of the semiconductor pillar group 310 and is in contact with the capacitor structure 306; and the second insulation layer 313 is in contact with the capacitor structure 306.

Here, the first insulation layer 312 may be used to isolate the gate structures 308 that are respectively in contact with the two semiconductor pillars 335 of the semiconductor pillar group 310, and may also be used to isolate the gate structure 308 from the capacitor structure 306. In some examples, a material of the first insulation layer 312 includes, but is not limited to, silicon oxide. Here, a material of the second insulation layer 313 may be used to isolate adjacent ones of the semiconductor pillar groups 310. In some examples, the material of the second insulation layer 313 includes, but is not limited to, silicon oxide. The isolation structure 311 may further include an air gap 338 in the second insulation layer 313 or include a conductive structure in the second insulation layer 313.

In some examples, a material of the second dielectric layer 304 includes first silicon boronitride, and a formation temperature of the first silicon boronitride ranges from 500° C. to 700° C.; and a material of the first dielectric layer 303 includes at least one of: second silicon boronitride, silicon nitride in a topological structure, and aluminum oxide, where a formation temperature of the second silicon boronitride ranges from 200° C. to 500° C.

It is to be noted that the materials of the first insulation layer 312, the second insulation layer 313, the first dielectric layer 303, and the second dielectric layer 304 given in the above examples are merely examples, and the examples of the present disclosure are not limited thereto. For the selection of materials of the first insulation layer 312, the second insulation layer 313, the first dielectric layer 303 and the second dielectric layer 304, it is necessary to consider that an impact on the first insulation layer 312, the second insulation layer 313 and the second dielectric layer 304 is within an acceptable range during the first wet etching on the first dielectric layer 303.

In some examples, an etching-selectivity ratio of the material of the first dielectric layer 303 to the material of the first insulation layer 312 is greater than 10:1, and an etching-selectivity ratio of the material of the first dielectric layer 303 to the material of the second insulation layer 313 is greater than 10:1.

In some examples, an etching-selectivity ratio of the material of the first dielectric layer 303 to the material of the second dielectric layer 304 is greater than 10:1.

It is to be noted that the ranges of the etching-selectivity ratios given in the above examples are merely examples, and the examples of the present disclosure are not limited thereto. The ranges of the above-mentioned etching-selectivity ratios may be adaptively adjusted according to actual process requirements as long as the impact on the first insulation layer 312, the second insulation layer 313, and the second dielectric layer 304 is within the acceptable range during the first wet etching on the first dielectric layer 303.

In some examples, as shown in FIG. 7, the stack sub-structure 305 includes a first conductive layer 314, a first support layer 315, a second conductive layer 316, and a second support layer 317 stacked along the first direction; the capacitor structure 306 includes a first electrode plate 318, a dielectric layer 319, a second electrode plate 320, and a support structure 322; the first electrode plate 318 extends into the second dielectric layer 304 and the first dielectric layer 303 from the stack sub-structure 305 along the first direction; the support structure 322 is located in the stack sub-structure 305 and extends along the first direction, and the first electrode plate 318 surrounds the support structure 322; a portion of the second electrode plate 320 surrounds the first conductive layer 314 and the second conductive layer 316; the dielectric layer 319 is located between the first electrode plate 318 and the second electrode plate 320; and a size of a portion of the support structure 322 and the first electrode plate 318 located in the stack sub-structure 305 along the second direction is greater than the size of the portion of the capacitor structure 306 located in the second dielectric layer 304 along the second direction.

In some examples, a material of the support structure 322 includes, but is not limited to, polysilicon and an insulation material, and the insulation material may be, for example, silicon oxide and/or silicon nitride. The first electrode plate 318 may serve as a lower electrode of the capacitor structure 306, and the second electrode plate 320 may serve as an upper electrode of the capacitor structure 306. A material of the dielectric layer 319 includes a high dielectric-constant (high-K) material. In an example, the material of the dielectric layer 319 may include, but is not limited to, aluminum oxide (Al₂O₃), zirconium oxide (ZrO₂), hafnium oxide (HfO₂), etc. A material of the first electrode plate 318 may include a conductive material, which may be titanium nitride, for example. A material of the second electrode plate 320 may include a conductive material, which may be titanium nitride, for example. Materials of the first conductive layer 314 and the second conductive layer 316 may be the same, and the material of the first conductive layer 314 and the second conductive layer 316 includes a conductive material, which may be silicon germanium, in a non-limiting example.

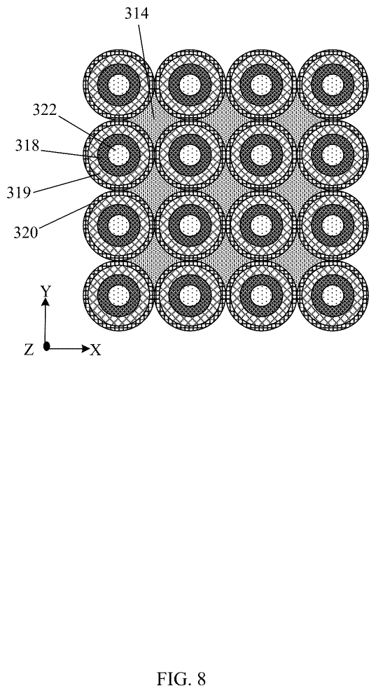

As shown in FIGS. 7 and 8, a top face of the first electrode plate 318 may be lower than a top face of the second support layer 317. The dielectric layer 319 is located not only between the second dielectric layer 304 and the first support layer 315 but also between the first support layer 315 and the second support layer 317, and part of the dielectric layer 319 is located on the top face of the first electrode plate 318 in the second support layer 317 and also located on the second support layer 317 and the support structure 322. The second electrode plate 320 is located between the second dielectric layer 304 and the first support layer 315 and also located between the first support layer 315 and the second support layer 317, and part of the second electrode plate 320 is located on the dielectric layer 319 on the second support layer 317 and the support structure 322. The dielectric layer 319 separates the first electrode plate 318 from the second electrode plate 320. The first conductive layer 314 and the second conductive layer 316 may be formed in the same process, and when the first conductive layer 314 and the second conductive layer 316 are formed, a third conductive layer 339 may also be formed in the same process. As shown in FIG. 7, the third conductive layer 339 is located on the second electrode plate 320 on the second support layer 317 and the support structure 322. Materials of the first conductive layer 314, the second conductive layer 316, and the third conductive layer 339 are the same.

FIG. 8 is a cross-sectional view of FIG. 7 along a direction BB′. As shown in FIG. 8, the first conductive layer 314 is in contact with all the second electrode plates 320 of the plurality of capacitor structures 306. The second electrode plate 320 surrounds the dielectric layer 319; the dielectric layer 319 surrounds the first electrode plate 318; and the first electrode plate 318 surrounds the support structure 322.

In some examples, the second conductive layer 316 is in contact with all the second electrode plates 320 of the plurality of capacitor structures, and the first conductive layer 314 is in contact with the second conductive layer 316, and the second conductive layer 316 is in contact with the third conductive layer 339.

It is to be noted that the support structure 322 is located only in the stack sub-structure 305 in the examples shown in FIG. 7, although the support structure 322 may be also located in the second dielectric layer 304 and may even extend into the first dielectric layer 303, while the bottom of the support structure 322 is surrounded by the first electrode plate 318. That is to say, the portion of the capacitor structure 306 in contact with the contact structure 321 is only the first electrode plate 318 of the capacitor structure 306.

In some examples, a material of the first dielectric layer 303 is different from a material of the first support layer 315, and is different from a material of the second support layer 317.

For the selection of materials of the first support layer 315 and the second support layer 317, it is necessary to consider the following aspects: first, an impact on the first support layer 315 and the second support layer 317 is within an acceptable range during the first wet etching on the first dielectric layer 303; second, an impact on the first support layer 315 and the second support layer 317 is within an acceptable range when removing the first sacrificial layer 331 and the second sacrificial layer 332; and third, the materials of the first support layer 315 and the second support layer 317 may be an insulation material, so as to separate the first electrode plates 318 of adjacent ones of the capacitor structures 306.

In some examples, the material of the first support layer 315 includes, but is not limited to, silicon carbonitride. The material of the second support layer 317 includes, but is not limited to, silicon carbonitride and silicon nitride.

In some examples, an etching-selectivity ratio of the material of the first dielectric layer 303 to the material of the first support layer 315 is greater than 10:1, and an etching-selectivity ratio of the material of the first dielectric layer 303 to the material of the second support layer 317 is greater than 10:1.

It is to be noted that the ranges of the etching-selectivity ratios given in the above examples are provided by way of example and not limitation, and the examples of the present disclosure are not limited thereto. The ranges of the etching-selectivity ratios may be adaptively adjusted according to actual process requirements.

In some examples, the size of the portion of the capacitor structure 306 located in the first dielectric layer 303 along the second direction ranges from 16 nm to 55 nm, the size of the portion of the capacitor structure 306 located in the second dielectric layer 304 along the second direction ranges from 10 nm to 40 nm, and the size of the portion of the support structure 322 and the first electrode plate 318 located in the stack sub-structure 305 along the second direction ranges from 10 nm to 40 nm.

In some examples, a side of the portion of the capacitor structure 306 located in the first dielectric layer 303 that is in contact with the second dielectric layer 304 is a plane.

Here, a side of the portion of the capacitor structure 306 located in the first dielectric layer 303 that is in contact with the second dielectric layer 304 being a plane may be construed as the face of the portion of the capacitor structure 306 located in the first dielectric layer 303 that is in contact with the second dielectric layer 304 and is a straight line in the cross-sectional view as shown in FIG. 7. Here, when a portion of a through hole in the initial stack structure that is located in the first dielectric layer 303 is enlarged by the first wet etching, since the first dielectric layer 303 has a higher selectivity ratio than the second dielectric layer 304 such that only the first dielectric layer 303 will be consumed and the consumption of the second dielectric layer 304 is negligible, the face of the portion of the capacitor structure 306 located in the first dielectric layer 303 that is in contact with the second dielectric layer 304 is a plane.

In some examples, as shown in FIG. 7, the first semiconductor structure 301 further includes a plurality of contact structures 321 extending along the first direction; and one of two opposite ends of the semiconductor pillar 335 along the first direction is in contact with the contact structure 321.

In some examples, a material of the contact structure 321 may include a conductive material. Here, the conductive material may be one of a doped semiconductor material (e.g., doped silicon, doped germanium, etc.), a conductive metal nitride (e.g., titanium nitride, tantalum nitride, etc.), a metal material (e.g., tungsten, titanium, tantalum, etc.), and a metal semiconductor compound (e.g., tungsten silicide, cobalt silicide, titanium silicide, nickel silicide, etc.).

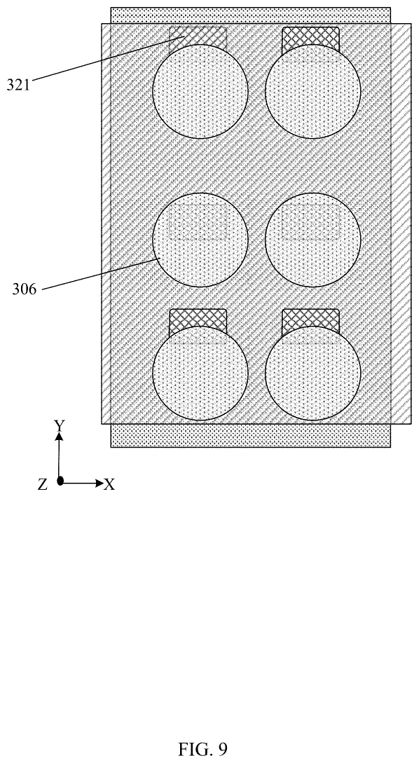

FIG. 9 is a cross-sectional view of FIG. 7 along a direction AA′. It is to be noted that in order to show the contact between the contact structure 321 and the capacitor structure 306 more clearly in FIG. 9, FIG. 9 is a perspective view of a cross section of FIG. 7 along the direction AA′, with some structures being omitted.

In some examples, as shown in FIG. 9, the contact structure 321 includes a first end face and a second end face that are opposite along the first direction; the capacitor structure 306 includes a third end face and a fourth end face that are opposite along the first direction; and at least part of the first end face is in contact with the third end face.

Here, at least part of the first end face being in contact with the third end face may be construed as that the entire first end face may be in contact with the third end face, or a portion of the first end face may be in contact with the third end face.

In some examples, a ratio of an area of a portion of the first end face in contact with the third end face to an area of the first end face ranges from 25% to 100%.

In the examples of the present disclosure, by providing the first dielectric layer 303, the size of the bottom of the capacitor structure 306 is enlarged so that the contact area between the contact structure 321 and the capacitor structure 306 can be increased, and the performance of the semiconductor device 300 can be improved. In the examples of the present disclosure, the ratio of the area of the portion of the first end face in contact with the third end face to the area of the first end face may even reach 100%, e.g., the entire first end face is in contact with the third end face. In the examples of the present disclosure, the ratio of the area of the portion of the first end face of some contact structures 321 in contact with the third end face to the area of the first end face may reach 100%, and the ratio of the area of the portion of the first end face of some other contact structures 321 in contact with the third end face to the area of the first end face may be less than 100%.

In some examples, the first end face of at least some of the contact structures 321 is in contact with both the third end face and the first dielectric layer 303.

Here, the first end face of at least some of the contact structures 321 being in contact with both the third end face and the first dielectric layer 303 may be construed as the first end face of some of the contact structures 321 having a portion not in contact with the third end face, or the first end face of all the contact structures 321 having a portion not in contact with the third end face.

In some examples, the size of the contact structure 321 along the second direction ranges from 4 nm to 20 nm.

It may be understood that a range of the size of the contact structure 321 along the second direction is small, which brings a great challenge for the contact area of the contact structure 321 and the capacitor structure 306 to meet a certain requirement. In the examples of the present disclosure, by providing the first dielectric layer 303, a size of the bottom of the capacitor structure 306 is enlarged so that the contact area of the contact structure 321 and the capacitor structure 306 can be increased, thereby reducing process difficulty, increasing the process window and being conducive to improving the performance of the semiconductor device.

In some examples, as shown in FIG. 3, the semiconductor device 300 further includes a second semiconductor structure 327, where the first semiconductor structure 301 and the second semiconductor structure 327 are stacked along the first direction, and the second semiconductor structure 327 includes a peripheral circuit 341.

In some examples, the first semiconductor structure 301 and the second semiconductor structure 327 may be arranged in juxtaposition along the direction perpendicular to the first direction, or may be arranged as being stacked along the first direction. Compared with the solution that the first semiconductor structure 301 and the second semiconductor structure 327 are arranged in juxtaposition along the direction perpendicular to the first direction, the first semiconductor structure 301 and the second semiconductor structure 327 are arranged as being stacked along the first direction, which may save more area of the semiconductor device 300. Here, the first direction may be construed as a thickness direction of the semiconductor device 300, which is also an extending direction of the semiconductor pillar in the vertical gate transistor. The first semiconductor structure 301 and the second semiconductor structure 327 may be formed on the same wafer; or the first semiconductor structure 301 and the second semiconductor structure 327 may be formed on different wafers and then bonded such that the first semiconductor structure 301 and the second semiconductor structure 327 are stacked along the first direction.

Based on the concept similar to the semiconductor device in the above examples, as shown in FIG. 2, examples of the present disclosure further provide a memory 20 including the semiconductor device described in any of the above examples.

The above-mentioned memory has been illustrated in detail with respect to FIG. 2 in the above examples, which will no longer be described here for brevity.

Based on the concept similar to the semiconductor device in the above examples, as shown in FIG. 1, examples of the present disclosure further provide a memory system 30 including a controller 10 and the memory 20 as described in any of the above examples. The controller 10 is configured to control the memory 20.

The above-mentioned memory system 30 has been illustrated in detail in the foregoing examples with respect to FIG. 1, which will no longer be described here for brevity.

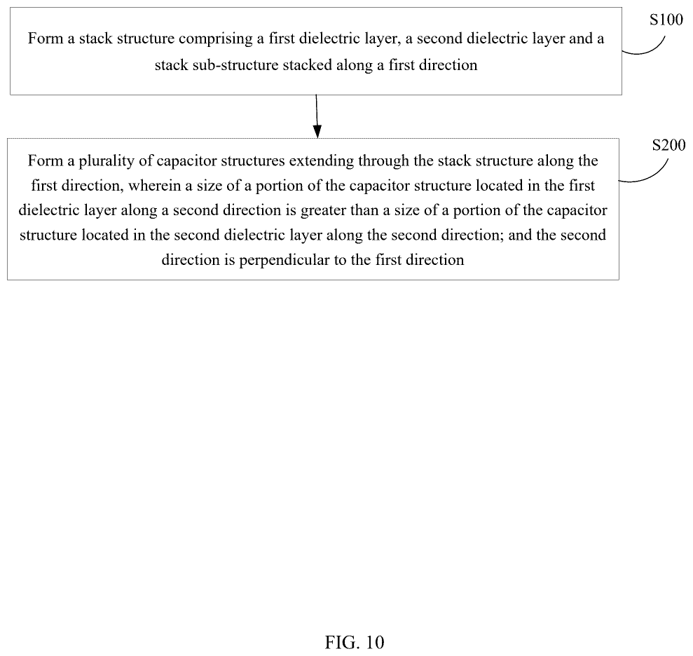

Based on the concept similar to the semiconductor device in the above examples, examples of the present disclosure further provide a manufacturing method of a semiconductor device. FIG. 10 is a flow diagram illustrating a manufacturing method of a semiconductor device according to examples of the present disclosure. With reference to FIG. 10, the manufacturing method includes: forming a first semiconductor structure, where forming the first semiconductor structure includes:
S100: forming a stack structure including a first dielectric layer, a second dielectric layer, and a stack sub-structure stacked along a first direction; and
S200: forming a plurality of capacitor structures extending through the stack structure along the first direction, where a size of a portion of the capacitor structure located in the first dielectric layer along a second direction is greater than a size of a portion of the capacitor structure located in the second dielectric layer along the second direction; and the second direction is perpendicular to the first direction.

It should be understood that the operations as illustrated in FIG. 10 are not exclusive, and other operations may be also performed before, after, or between any of the illustrated operations. The sequence of the operations illustrated in FIG. 10 can be adjusted according to actual needs.

In the examples of the present disclosure, adding the first dielectric layer may lead to an increased size of the bottom of the capacitor structure along the second direction, an increased contact area between the contact structure and the capacitor structure, and an enlarged process window, so that the contact structure can still be in good contact with the bottom of the capacitor structure in the case where the size of the contact structure in contact with the bottom of the capacitor structure is small and there is an offset between the center of the contact structure and the center of the capacitor structure in design. Thus, the performance of the semiconductor device can be improved.

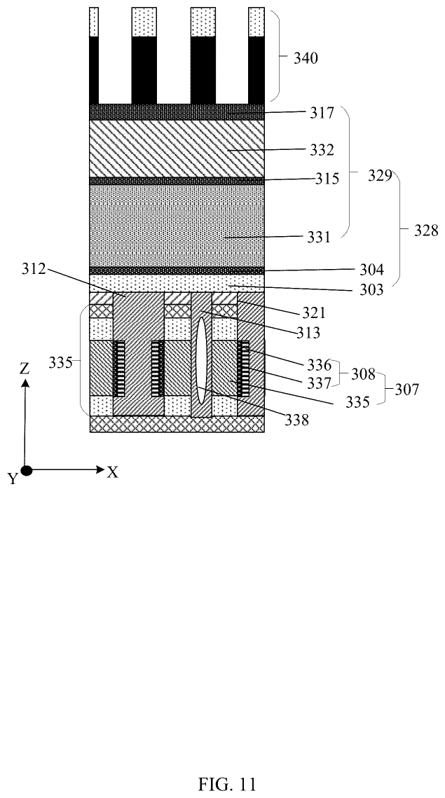

FIGS. 11 to 18 are schematic diagrams illustrating a formation process of a semiconductor device according to examples of the present disclosure. A method of forming a semiconductor device provided by examples of the present disclosure will be illustrated with reference to FIGS. 11 to 18.

In some examples, forming the stack structure and forming the plurality of capacitor structures includes providing an initial stack structure including the first dielectric layer, the second dielectric layer and an initial stack sub-structure stacked along the first direction, where the initial stack sub-structure includes a first sacrificial layer, a first support layer, a second sacrificial layer and a second support layer stacked along the first direction.

As shown in FIG. 11, an initial stack structure 328 is provided, which includes the first dielectric layer 303, the second dielectric layer 304 and the initial stack sub-structure 329 stacked along the first direction, where the initial stack sub-structure includes the first sacrificial layer 331, the first support layer 315, the second sacrificial layer 332 and the second support layer 317 stacked along the first direction. A patterned mask layer 340 is further formed on the initial stack structure 328.

In some examples, a material of the first sacrificial layer 331 includes, but is not limited to, borophosphosilicate glass (BPSG), and a material of the second sacrificial layer 332 includes, but is not limited to, tetraethyl orthosilicate (TEOS).

In some examples, the initial stack structure 328 and the mask layer 340 may be formed by a thin film deposition process.

In the examples of the present disclosure, the thin film deposition process includes, but is not limited to, chemical vapor deposition (CVD), low pressure chemical vapor deposition (LPCVD), plasma enhanced chemical vapor deposition (PECVD), physical vapor deposition (PVD) and atomic layer deposition (ALD).

In some examples, as shown in FIG. 11, forming the first semiconductor structure 301 further includes: forming a plurality of vertical gate transistors 307, where each of the vertical gate transistors 307 is coupled to a corresponding one of the capacitor structures formed in a subsequent process; and the vertical gate transistor 307 includes a semiconductor pillar 335 extending along the first direction and a gate structure 308 in contact with at least part of a side of the semiconductor pillar 335.

In some examples, a distance between one of two semiconductor pillars 335 adjacent to a first semiconductor pillar of a plurality of semiconductor pillars 335 along the second direction and the first semiconductor pillar is a first distance, and a distance between the other one of the two semiconductor pillars 335 and the first semiconductor pillar is a second distance; and the first distance is greater than the second distance.

In some examples, the plurality of semiconductor pillars 335 constitute a plurality of semiconductor pillar groups, and the semiconductor pillar group includes two semiconductor pillars 335 arranged along the second direction; the gate structure 308 is located between the two semiconductor pillars 335 of the semiconductor pillar group, and a distance between the two semiconductor pillars 335 of the semiconductor pillar group is the first distance; forming the first semiconductor structure 301 further includes: forming an isolation structure located between adjacent ones of the semiconductor pillar groups along the second direction, and a distance between two adjacent ones of the semiconductor pillar groups along the second direction is the second distance.

In some examples, as shown in FIG. 11, forming the first semiconductor structure 301 further includes: forming a plurality of contact structures 321 extending along the first direction, where one of two opposite ends of the semiconductor pillar 335 along the first direction is in contact with the contact structure 321.

In some examples, the above-mentioned contact structure 321 may be formed by forming a hole in a corresponding dielectric layer and filling the hole with a conductive material; or a metal material layer may be formed on an end of the semiconductor pillar 335 close to the capacitor structure, and thermal treatment is performed on the semiconductor pillar 335 and the metal material layer, thereby forming the contact structure 321 made of a metal semiconductor compound.

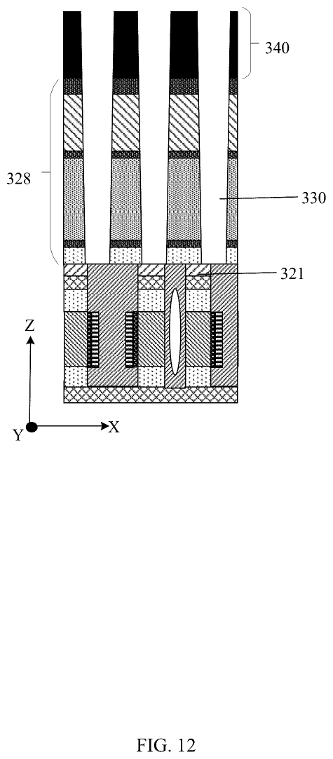

In some examples, as shown in FIG. 12, the initial stack structure 328 is etched to form a plurality of through holes 330 extending through the initial stack structure 328 along the first direction.

In some examples, the initial stack structure 328 may be etched by a dry etching process to form a plurality of through holes 330 extending through the initial stack structure 328 along the first direction.

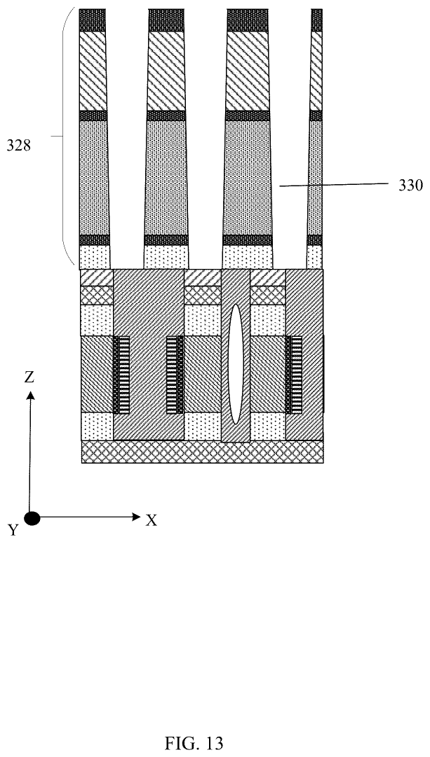

In some examples, as shown in FIG. 13, after etching the initial stack structure 328 to form the plurality of through holes 330 extending through the initial stack structure 328 along the first direction. The mask layer 340 may be removed.

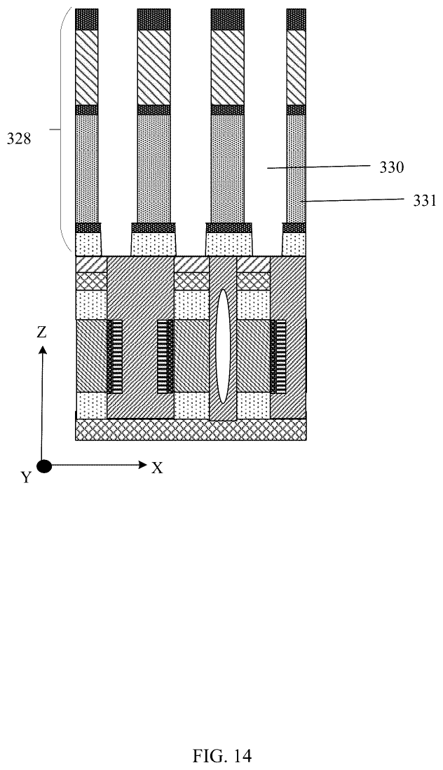

In some examples, as shown in FIG. 14, forming the plurality of capacitor structures further includes: performing second wet etching on the through hole 330 such that the size of the through hole 330 located in the first sacrificial layer 331 along the second direction is enlarged.

It may be understood that the through hole 330 formed by dry etching generally presents a shape with a large top and a small bottom as shown in FIG. 13. In the examples of the present disclosure, the size of the portion of the through hole 330 located in the first sacrificial layer 331 may be appropriately enlarged by the second wet etching. Here, the second wet etching may be cleaning after forming the through hole 330 by dry etching.

In some examples, a dilute sulfuric peroxide (DSP) mixture may be used in the second wet etching.

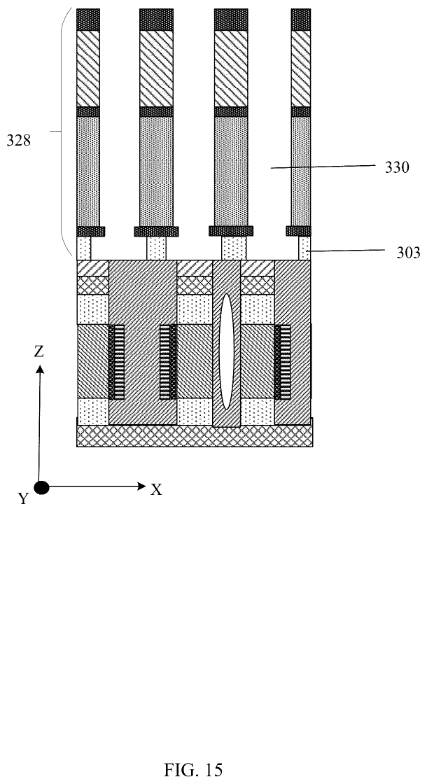

In some examples, as shown in FIG. 15, first wet etching is performed on the first dielectric layer 303 such that a size of a portion of the through hole 330 located in the first dielectric layer 303 along the second direction is greater than a size of a portion of the through hole 330 located in the second dielectric layer 304 along the second direction.

In some examples, as shown in FIG. 11, forming the first semiconductor structure 301 further includes: forming a first insulation layer 312; forming the isolation structure includes: forming a second insulation layer 313; the first insulation layer 312 is located between the two semiconductor pillars 335 of the semiconductor pillar group 310 and is in contact with the capacitor structure 306; the second insulation layer 313 is in contact with the capacitor structure 306; an etching-selectivity ratio of a material of the first dielectric layer 303 to a material of the first insulation layer 312 is greater than 10:1; and an etching-selectivity ratio of the material of the first dielectric layer 303 to a material of the second insulation layer 313 is greater than 10:1.

In some examples, an etching-selectivity ratio of the material of the first dielectric layer 303 to the material of the second dielectric layer 304 is greater than 10:1.

In some examples, a material of the second dielectric layer 304 includes first silicon boronitride, and a formation temperature of the first silicon boronitride ranges from 500° C. to 700° C.; and a material of the first dielectric layer 303 includes at least one of: second silicon boronitride, silicon nitride in a topological structure, and aluminum oxide, where a formation temperature of the second silicon boronitride ranges from 200° C. to 500° C.

In some examples, an etching-selectivity ratio of the material of the first dielectric layer 303 to the material of the second dielectric layer 304 is greater than 10:1, and an etching-selectivity ratio of the material of the first dielectric layer 303 to a material of the initial stack sub-structure 329 is greater than 10:1.

In the examples of the present disclosure, the material of the first dielectric layer 303 has a large etching-selectivity ratio with respect to the second dielectric layer 304, the initial stack sub-structure 329, the first insulation layer 312 and the second insulation layer 313, such that the impact on the second dielectric layer 304, the initial stack sub-structure 329, the first insulation layer 312 and the second insulation layer 313 is small during the first wet etching.

In the examples of the present disclosure, by performing the first wet etching on the first dielectric layer 303, the size of the portion of the through hole 330 located in the first dielectric layer 303 is enlarged so that the capacitor structure 306 subsequently formed in the through hole 330 can have a large contact area with the contact structure 321, thereby increasing the process window and reducing process complexity.

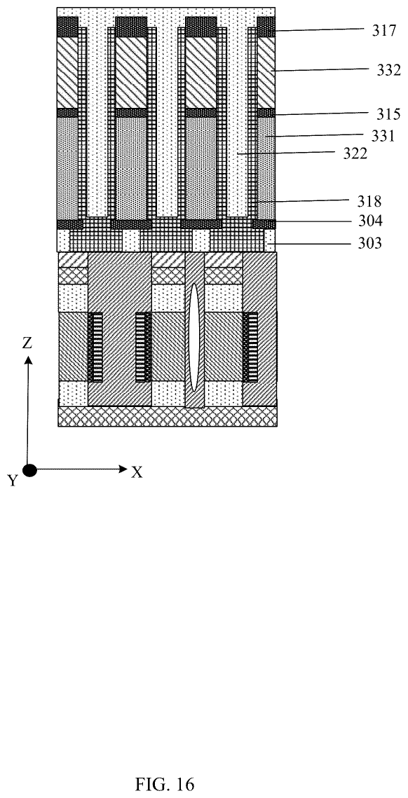

In some examples, as shown in FIG. 16, forming the plurality of capacitor structures further includes: forming a first electrode plate 318 on a sidewall and a bottom wall of the through hole 330; and forming a support structure 322 covering the first electrode plate 318 in the through hole 330 where the first electrode plate 318 is formed.

In some examples, as shown in FIG. 16, the support structure 322 is further formed on the second support layer 317. A method of forming the above-mentioned first electrode plate 318 and a method of forming the support structure 322 include a deposition process. A top face of the first electrode plate 318 may be lower than a top face of the second support layer 317, as shown in FIG. 16. In some other examples, the top face of the first electrode plate 318 may be flush with the top face of the second support layer 317.

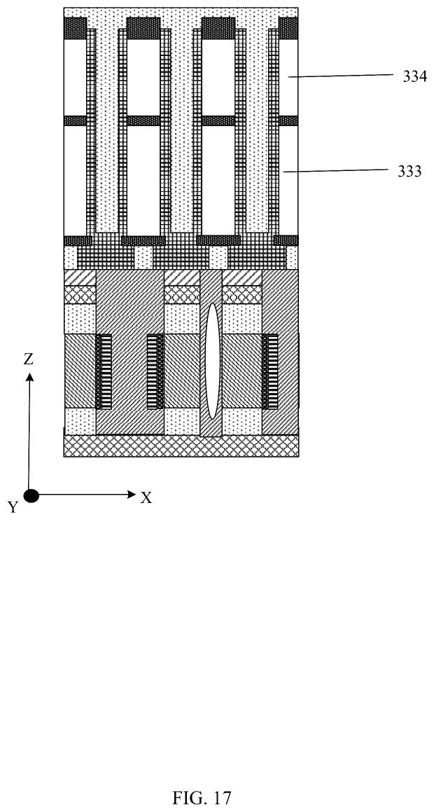

In some examples, as shown in FIG. 17, forming the plurality of capacitor structures further includes: removing the first sacrificial layer 331 to form a first filling region 333, and removing the second sacrificial layer 332 to form a second filling region 334.

In some examples, a method of removing the first sacrificial layer 331 to form the first filling region 333 and removing the second sacrificial layer 332 to form the second filling region 334 includes a wet etching process.

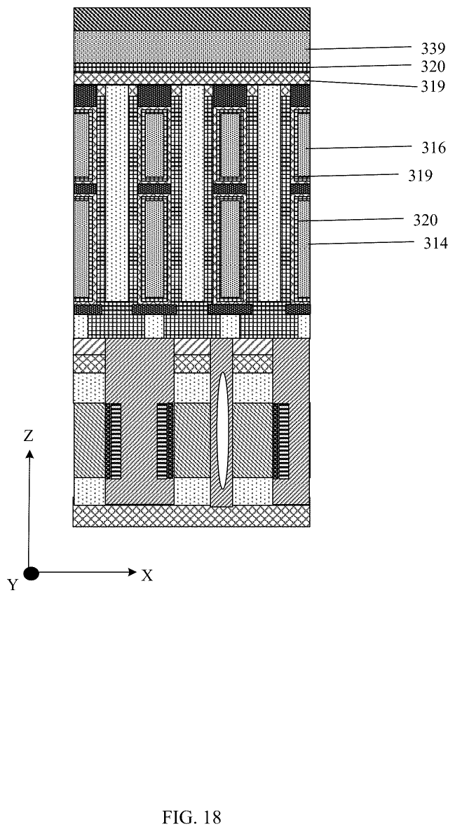

In some examples, as shown in FIG. 18, forming the plurality of capacitor structures further includes: removing a portion of the support structure 322 such that the top face of the first electrode plate 318 is exposed. The support structure 322 may be planarized by a planarization process such that a top face of the support structure 322 is flush with the top face of the second support layer 317.

In some examples, as shown in FIG. 18, forming the plurality of capacitor structures further includes: forming a dielectric layer 319 and a second electrode plate 320 on the first filling region 333, the second filling region 334 and the second support layer 317, where the dielectric layer 319 is located between the first electrode plate 318 and the second electrode plate 320. In some examples, as shown in FIG. 18, forming the plurality of capacitor structures further includes: forming a first conductive layer 314 in the first filling region 333, and forming a second conductive layer 316 in the second filling region 334, where the second electrode plate 320 surrounds the first conductive layer 314 and the second conductive layer 316.

In some examples, forming the dielectric layer 319 on the first filling region 333, the second filling region 334, and the second support layer 317 may be performed in the same process. In some examples, as shown in FIG. 18, the dielectric layer 319 is also formed in the second support layer 317. The dielectric layer 319 is located between the second electrode plate 320 and the first electrode plate 318 to isolate the first electrode plate 318 from the second electrode plate 320.

In some examples, a method of forming the first electrode plate 318, the second electrode plate 320, the dielectric layer 319, the first conductive layer 314 and the second conductive layer 316 described above includes a deposition process. Forming the plurality of capacitor structures further includes forming a third conductive layer 339 that is located on the second electrode plate 320 on the second support layer 317 and the support structure 322. Materials of the first conductive layer 314, the second conductive layer 316 and the third conductive layer 339 are the same, and the first conductive layer 314, the second conductive layer 316 and the third conductive layer 339 may be formed in the same process.

In some examples, the manufacturing method further includes forming a second semiconductor structure including a peripheral circuit; and bonding the first semiconductor structure and the second semiconductor structure such that the first semiconductor structure and the second semiconductor structure are stacked along the first direction.

In some examples, the second semiconductor structure may be bonded to the first semiconductor structure by a hybrid bonding process.

It is to be noted that the examples of the present disclosure are not limited to the solution of bonding the first semiconductor structure and the second semiconductor structure such that the first semiconductor structure and the second semiconductor structure are stacked along the first direction as mentioned in the above examples, and may also include a solution that the first semiconductor structure and the second semiconductor structure stacked along the first direction are formed on the same wafer.

The features disclosed in several device examples provided by the present disclosure may be combined arbitrarily to obtain a new device example without conflict.

The methods disclosed in several method examples provided by the present disclosure may be combined arbitrarily to obtain a new method example without conflict.

The above descriptions are merely specific implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure.

What is claimed is:

1. A semiconductor device, comprising:
a first semiconductor structure, comprising:
a stack structure comprising a first dielectric layer, a second dielectric layer, and a stack sub-structure stacked along a first direction; and
a plurality of capacitor structures extending through the stack structure along the first direction, wherein a size of a portion of the capacitor structure located in the first dielectric layer along a second direction is greater than a size of a portion of the capacitor structure located in the second dielectric layer along the second direction; and the second direction is perpendicular to the first direction.

2. The semiconductor device of claim 1, wherein the first semiconductor structure further comprises:
a plurality of vertical gate transistors, wherein each of the vertical gate transistors is coupled to a corresponding one of the capacitor structures, and comprises a semiconductor pillar extending along the first direction and a gate structure in contact with at least part of a side of the semiconductor pillar.

3. The semiconductor device of claim 2, wherein a distance between one of two semiconductor pillars adjacent to a first semiconductor pillar of a plurality of semiconductor pillars along the second direction and the first semiconductor pillar is a first distance, and a distance between the other one of the two semiconductor pillars and the first semiconductor pillar is a second distance; and the first distance is greater than the second distance.

4. The semiconductor device of claim 3, wherein:
the plurality of semiconductor pillars include a plurality of semiconductor pillar groups, and the semiconductor pillar group comprises two semiconductor pillars arranged along the second direction; the gate structure is located between the two semiconductor pillars of the semiconductor pillar group, and a distance between the two semiconductor pillars of the semiconductor pillar group is the first distance; and
the first semiconductor structure further comprises an isolation structure located between adjacent ones of the semiconductor pillar groups along the second direction, and a distance between two adjacent ones of the semiconductor pillar groups along the second direction is the second distance.

5. The semiconductor device of claim 4, wherein the first semiconductor structure further comprises a first insulation layer, and the isolation structure comprises a second insulation layer; the first insulation layer is located between the two semiconductor pillars of a semiconductor pillar group and is in contact with the capacitor structure; the second insulation layer is in contact with a capacitor structure; an etching-selectivity ratio of a material of the first dielectric layer to a material of the first insulation layer is greater than 10:1; and an etching-selectivity ratio of the material of the first dielectric layer to a material of the second insulation layer is greater than 10:1.

6. The semiconductor device of claim 1, wherein an etching-selectivity ratio of a material of the first dielectric layer to a material of the second dielectric layer is greater than 10:1.

7. The semiconductor device of claim 1, wherein the stack sub-structure comprises a first conductive layer, a first support layer, a second conductive layer and a second support layer stacked along the first direction; a capacitor structure of the plurality of capacitor structure comprises a first electrode plate, a dielectric layer, a second electrode plate and a support structure; the first electrode plate extends into the second dielectric layer and the first dielectric layer from the stack sub-structure along the first direction; the support structure is located in the stack sub-structure and extends along the first direction, and the first electrode plate surrounds the support structure; a portion of the second electrode plate surrounds the first conductive layer and the second conductive layer; the dielectric layer is located between the first electrode plate and the second electrode plate; and
a size of a portion of the support structure and the first electrode plate located in the stack sub-structure along the second direction is greater than the size of the portion of the capacitor structure located in the second dielectric layer along the second direction.

8. The semiconductor device of claim 7, wherein a material of the first dielectric layer is different from a material of the first support layer, and is different from a material of the second support layer.

9. The semiconductor device of claim 7, wherein an etching-selectivity ratio of a material of the first dielectric layer to a material of the first support layer is greater than 10:1, and an etching-selectivity ratio of the material of the first dielectric layer to a material of the second support layer is greater than 10:1.

10. The semiconductor device of claim 1, wherein a side of the portion of a capacitor structure located in the first dielectric layer that is in contact with the second dielectric layer is a plane.

11. The semiconductor device of claim 2, wherein the first semiconductor structure further comprises a plurality of contact structures extending along the first direction; and one of two opposite ends of the semiconductor pillar along the first direction is in contact with the contact structure.

12. The semiconductor device of claim 11, wherein a contact structure comprises a first end face and a second end face that are opposite along the first direction; the capacitor structure comprises a third end face and a fourth end face that are opposite along the first direction; and at least part of the first end face is in contact with the third end face.

13. The semiconductor device of claim 12, wherein the first end face of at least some of the contact structures is in contact with both the third end face and the first dielectric layer.

14. The semiconductor device of claim 1, further comprising a second semiconductor structure, wherein the first semiconductor structure and the second semiconductor structure are stacked along the first direction, and the second semiconductor structure comprises a peripheral circuit.

15. A method of manufacturing a semiconductor device, comprising:
forming a first semiconductor structure, wherein forming the first semiconductor structure comprises:
forming a stack structure comprising a first dielectric layer, a second dielectric layer and a stack sub-structure stacked along a first direction; and
forming a plurality of capacitor structures extending through the stack structure along the first direction, wherein a size of a portion of the capacitor structure located in the first dielectric layer along a second direction is greater than a size of a portion of the capacitor structure located in the second dielectric layer along the second direction; and the second direction is perpendicular to the first direction.

16. The method of claim 15, wherein the forming the first semiconductor structure further comprises:
forming a plurality of vertical gate transistors, wherein each of the vertical gate transistors is coupled to a corresponding one of the capacitor structures, and comprises a semiconductor pillar extending along the first direction and a gate structure in contact with at least part of a side of the semiconductor pillar.

17. The method of claim 16, wherein a distance between one of two semiconductor pillars adjacent to a first semiconductor pillar of a plurality of semiconductor pillars along the second direction and the first semiconductor pillar is a first distance, and a distance between the other one of the two semiconductor pillars and the first semiconductor pillar is a second distance; and the first distance is greater than the second distance.

18. The method of claim 15, wherein the forming the stack structure and forming the plurality of capacitor structures comprise:
providing an initial stack structure comprising the first dielectric layer, the second dielectric layer and an initial stack sub-structure stacked along the first direction;
etching the initial stack structure to form a plurality of through holes extending through the initial stack structure along the first direction; and
performing first wet etching on the first dielectric layer such that a size of a portion of a through hole located in the first dielectric layer along the second direction is greater than a size of a portion of the through hole located in the second dielectric layer along the second direction.

19. The method of claim 18, wherein the initial stack sub-structure comprises a first sacrificial layer, a first support layer, a second sacrificial layer and a second support layer stacked along the first direction; and the forming the plurality of capacitor structures further comprises:
performing second wet etching on the through hole such that a size of a portion of the through hole located in the first sacrificial layer along the second direction is enlarged.

20. A memory device, comprising:
a semiconductor device, comprising:
a semiconductor structure, comprising:
a stack structure comprising a first dielectric layer, a second dielectric layer, and a stack sub-structure stacked along a first direction; and
a plurality of capacitor structures extending through the stack structure along the first direction, wherein a size of a portion of the capacitor structure located in the first dielectric layer along a second direction is greater than a size of a portion of the capacitor structure located in the second dielectric layer along the second direction; and the second direction is perpendicular to the first direction; and
a peripheral circuit coupled to the semiconductor device and configured to control at least one operation of the semiconductor device.
